(19) United States
(12) Patent Application Publication
(10) Pub. No.: US 2019/0163246 A1
(43) Pub. Date: May 30, 2019

(54) HEAT DISSIPATION SYSTEM OF ELECTRONIC DEVICE

(71) Applicant: Acer Incorporated, New Taipei City (TW)

(72) Inventors: Yu-Ming Lin, New Taipei City (TW); Wen-Neng Liao, New Taipei City (TW); Cheng-Wen Hsieh, New Taipei City (TW); Cheng-Yu Cheng, New Taipei City (TW); Shun-Ta Yu, New Taipei City (TW)

(73) Assignee: Acer Incorporated, New Taipei City (TW)

(21) Appl. No.: 16/199,237

(22) Filed: Nov. 26, 2018

(30) Foreign Application Priority Data
Nov. 27, 2017 (TW) 106141232

(51) Int. Cl. G06F 1/20; H05K 7/20

(52) U.S. Cl. CPC G06F 1/203; H05K 7/20336; H05K 7/20309

(57) ABSTRACT

A heat dissipation system of an electronic device including a body, at least one heat source, and a heat dissipation module is provided. The body has a stack tunnel, and the heat source is disposed in the body. The heat dissipation module includes an evaporator and a pipe connecting to the evaporator to form a loop, and a working fluid is filled in the loop. The evaporator is in thermal contact with the heat source to absorb heat generated from the heat source, and the heat is transferred to the loop through phase transition of the working fluid in the loop, such that the loop heats the air in the stack tunnel in a two-dimensional manner.

### CROSS-REFERENCE TO RELATED APPLICATION

This application claims the priority benefit of Taiwan application serial no. 106141232, filed on Nov. 27, 2017. The entirety of the above-mentioned patent application is hereby incorporated by reference herein and made a part of this specification.

### BACKGROUND

### Technical Field

The invention generally relates to a heat dissipation system, and particularly to a heat dissipation system of an electronic device.

### Description of Related Art

There is a constant trend toward thinner devices for the existing various types of electronic devices, not only for mobile phones, tablets, notebook monitors or docks, various displays such as computer monitors, TV monitors and the like, but also for an All-in-One PCs (AIO PCs, desktops integrating microprocessors, motherboards, hard drives, monitors and speakers into a single unit). Therefore, each component of the electronic device gradually stuff the interior space of the electronic device such that there is no enough space to accommodate a heat dissipation device in the electronic device. Otherwise it is bound to increase the thickness of the electronic device.

However, the processors, the display chips or the backlight module in the electronic devices gradually emit more and more heat for improving the performance or increasing the light-emitting area and the brightness, respectively. Therefore, providing the heat dissipation device but resulting in an increase in the overall thickness or reducing the provision of the heat dissipation device but resulting in easily overheating becomes a dilemma in the design of the electronic device.

For example, in order to make the All-in-One PCs have better heat dissipation efficiency, at least one fan is usually provided in the body for drawing cold air from the external environment as a heat dissipation means. However, in addition to the overall increase in volume and weight described above, other related problems such as the generation of noise during the operation of the fan and more power requirement from the fan to the power supply connected to the computer are resulted.

### SUMMARY

The invention provides a heat dissipation system of an electronic device, in which a heat dissipation module provides heat to air in a tunnel in a two-dimensional manner so as to enhance the stack effect in a body to increase the heat dissipation efficiency.

The heat dissipation system of the electronic device of the invention includes a body, at least one heat source and a heat dissipation module. The body has a stack tunnel, and the heat source is disposed in the body. The heat dissipation module includes an evaporator and a pipe connecting to the evaporator. The evaporator and the pipe form a loop, and a working fluid is filled in the loop. The evaporator is in thermal contact with the heat source and absorbs heat, and the heat generated from the heat source is transferred to the loop through phase transition of the working fluid, and the loop heats the air in the stack tunnel in a two-dimensional manner.

In view of the above, the heat dissipation system of the electronic device provides a heat transfer to the air in two-dimensional manner by forming a stack tunnel in the body, increasing the heat capacity of the heat source via the heat dissipation module, and expanding the contact with the air in the stack tunnel at the same time. Therefore, the electronic device can utilize the stack effect to achieve the heat dissipation effect, and at the same time, the structural restriction of the channel inlet resulted from the stack effect due to the position of the original heat source can be released.

To make the aforementioned features and advantages of the invention more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view of an electronic device according to an embodiment of the invention.

FIG. 2 is a side view of the electronic device of FIG. 1.

FIG. 3 and FIG. 4 respectively show the heat dissipation module of FIG. 1 and FIG. 2 from different perspectives.

FIG. 5A is a schematic view of a prior art stack tunnel.

FIG. 5B is a schematic view of the stack tunnel of the invention.

FIG. 5C is a schematic view of a stack tunnel according to another embodiment of the invention.

FIG. 6 is a schematic view of a heat dissipation module according to another embodiment of the invention.

### DESCRIPTION OF THE EMBODIMENTS

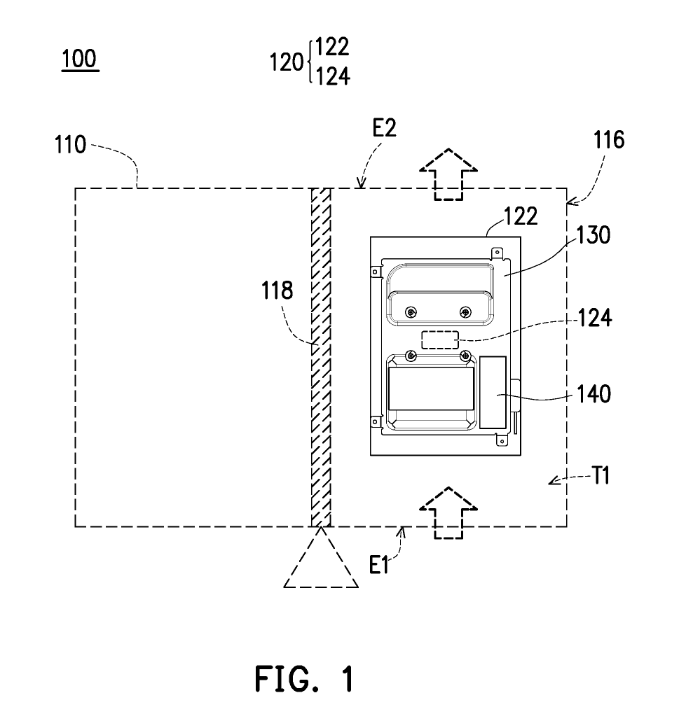

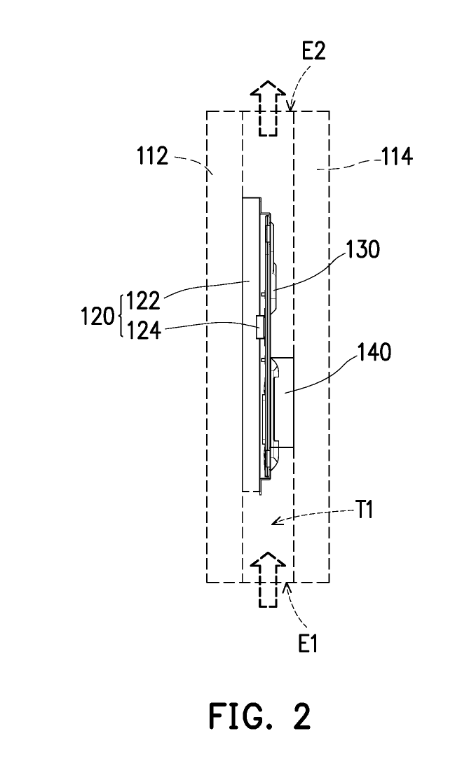

FIG. 1 is a schematic view of an electronic device according to an embodiment of the invention. FIG. 2 is a side view of the electronic device of FIG. 1. Referring to both of FIG. 1 and FIG. 2, it should be noted that since there are related electronic components 120 including a motherboard 122, a processor 124 on the motherboard 122 and a display chip (not shown) disposed in the electronic device 100 such as an all-in-one (AIO) computer device, the heat dissipation problem happening in other computer cases also presents in the electronic device 100. That is, heat generated from the processor 124 and/or the display chip during operation must be discharged out of the electronic device 100 to maintain the normal operation of the electronic device 100. Here, the processor 124 is regarded as a heat source in this embodiment. In the meantime, in order to further describe the means required for solving the heat dissipation problem, this embodiment only shows members and systems related to the heat dissipation in FIG. 1 and FIG. 2. Other technical features are all available from known techniques of All-in-One PCs and are not repeated herein. In addition, the body structure of the electronic device 100 is shown in phantom line in FIG. 1 and FIG. 2 to be distinguished from the members within the electronic device 100.

In this embodiment, the electronic device 100 includes a body 110 shown in hidden line, a heat source (taking the processor 124 as an example) and a heat dissipation module 130, wherein the body 110 further includes sidewalls 112 and 114, and the sidewall 112 is regarded as the side where the display is installed, and the sidewall 114 is regarded as the back cover of the body 110 (back to the display). Furthermore, the body 110 further includes sidewalls 116 and 118. Therefore, referring to both of FIG. 1 and FIG. 2, the above sidewalls 112, 114, 116 and 118 together form a stack tunnel T1 to accommodate the electronic components 120 and the heat dissipation module 130 within the stack tunnel T1. In the meantime, an inlet E1 and an outlet E2 are respectively disposed below and above the body 110 so that the stack tunnel T1 communicates with the external environment via the inlet E1 or the outlet E2. The ‘below’ and the ‘above’ described herein are based on the state of the electronic device 100 shown in FIG. 1 and FIG. 2. That is, based on the gravity direction, the forward direction is regarded as ‘below’, and the reverse direction is regarded as ‘above’.

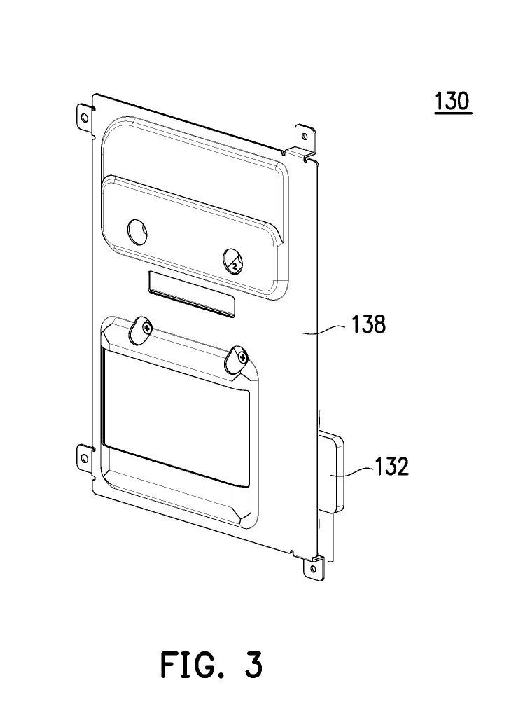

FIG. 3 and FIG. 4 respectively show the heat dissipation module of FIG. 1 and FIG. 2 from different perspectives. Referring to both of FIG. 3 and FIG. 4, in this embodiment, the heat dissipation module 130 includes an evaporator 132 and a pipe 134. The evaporator 132 and the pipe 134 are connected with each other to form a loop. A working fluid F1 (indicated by dotted arrows in FIG. 4) is filled in the loop and phase transition of the working fluid F1 occurs in the loop due to heat-absorbing and heat-releasing. Accordingly, the heat dissipation module 130 of this embodiment is a two-phase flow heat dissipation module, and more particularly, it is a two-phase close loop thermosyphon cooling system. The evaporator 132 is in thermal contact with the heat source to absorb heat, and the heat is transferred to the entire loop through phase transition of the working fluid F1. In this way, the air in the stack tunnel T1 is thus heated by the loop in a two-dimensional manner, and the heated air is further transferred out of the body 110 of the electronic device 100 via the outlet E2. In the meantime, the cold air in the external environment is thus transferred to the stack tunnel T1 via the inlet E1 for filling a space left by the exhausted heated air, thereby improving the stack effect to effectively dissipate heat generated from the heat source.

In detail, the heat dissipation module 130 further includes a heat pipe 136, an assembling element 131 and a plate 138. The assembling element 131 and the plate 138 are respectively locked on the motherboard 122 so that the heat pipe 136 is clamped between the assembling element 131 and the plate 138, and the hot end 136a of the heat pipe 136 abuts on the processor 124 (structurally direct contact or contact via a thermal conducting medium). In the meantime, since the cold end 136b of the heat pipe 136 abuts on the evaporator 132, the heat pipe 136 may absorb heat generated from the processor 124 at the hot end 136a and then transfer the heat to the evaporator 132 at the cold end 136b. Since the structure and the technique of the heat pipe 136 can be known from the prior art, they will not be repeated herein.

Next, after absorbing the heat, the evaporator 132 is able to drive the transition of the working fluid F1 from a liquid state to a vapor state in the evaporator 132 and then the working fluid F1 further flows to the pipe 134 from the evaporator 132. Since the working fluid F1 in the pipe 134 is in thermal contact with the air in the stack tunnel T1, the heat is transferred to the air in the stack tunnel T1 to heat the air. Therefore, as the heat moves out of the pipe 134, phase transition of the working fluid F1 therein from the vapor state to the liquid state occurs, and the working fluid F1 flows back to the evaporator 132 accordingly to repeat the heat-absorbing operation as described above. In the drawings, the dotted arrows F1 are used to show the flow direction of the working fluid F1 after the phase transition due to the heat-absorbing and the heat-releasing.

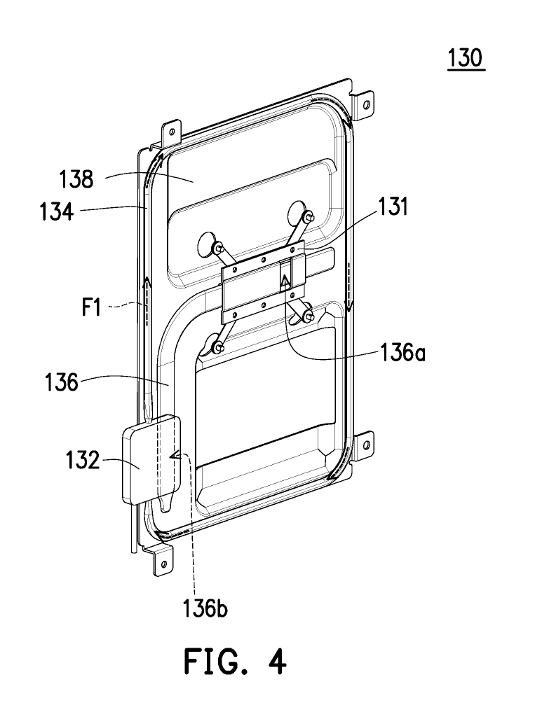

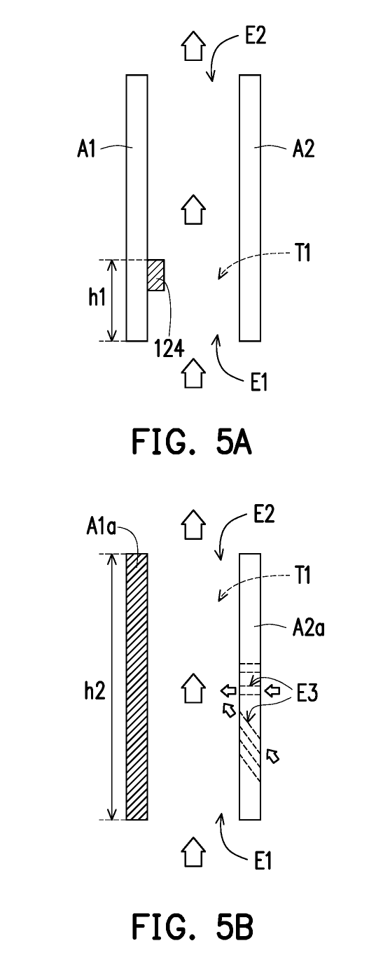

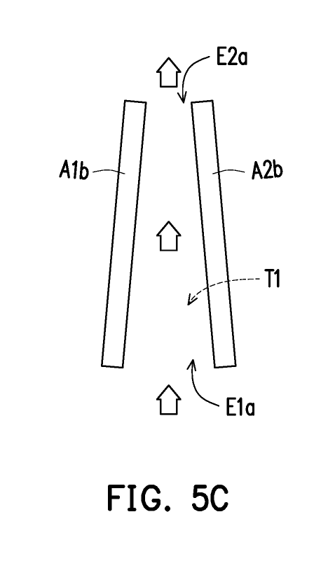

FIG. 5A is a schematic view of a prior art stack tunnel. FIG. 5B is a schematic view of the stack tunnel of the invention. Referring to both of FIG. 5A and FIG. 5B, the differences between the two are shown by simple schematic diagrams here. As shown in FIG. 5A, the sidewalls A1 and A2 form the stack tunnel T1 in the prior art electronic device, wherein there are different stack effects due to different locations of the heat source (taking the processor 124 as an example). For example, the heat source located in the stack tunnel T1 has a relative height (distance) h1 relative to the bottom of the sidewall A1 of the body. Therefore, in order to allow the stack effect occurs in the body successfully, the air in the external environment can only enter the stack tunnel T1 through the position below the heat source, i.e., the inlet E1. In this situation, if the inlet is disposed in a position above the heat source (i.e., a position higher than the relative height h1), the stack effect cannot occur successfully. In other words, to dissipate heat in the prior art, it is necessary to consider the position of the heat source in the body, and thus considerable structural restrictions are imposed on the arrangement of the inlet.

In contrast, rather than the point heat source (one-dimensional manner) shown in FIG. 5A as described above, the invention provides heat in the stack tunnel T1 in a two-dimensional manner by disposing the heat dissipation module 130 as shown in FIG. 1 to FIG. 4 as described above and as simply schematically shown in FIG. 5B. In the embodiment shown in FIG. 3 and FIG. 4, the plate 138 and the loop form a surface heat source to heat the air in the stack tunnel T1. In this way, by comparing FIG. 5A with FIG. 5B, it can be clearly known that corresponding to the sidewall A1a in the embodiment shown in FIG. 5B, the plate 138 and the loop may be regarded as the sidewall structure of the stack tunnel T1 to heat the air in the stack tunnel T1 in the two-dimensional manner. Therefore, in this situation, the inlet via which the cold air in the external environment enter the stack tunnel T1 is able to be disposed on any location in the entire range of the relative height h2 (equal to the entire range of the sidewalls A1a and A2a). That is, the inlet is not limited to the inlet E1 shown in the figure. For example, a plurality of inlets E3 are thus able to be disposed on the sidewalls A2a to increase opportunities for the cold air in the external environment to enter the stack tunnel without affecting the stack effect. Compared with the restricted stack tunnel shown in FIG. 5A, the stack tunnel shown in FIG. 5B increases the heat dissipation efficiency thereby.

FIG. 5C is a schematic view of a stack tunnel according to another embodiment of the invention. Differently from the foregoing, the sidewalls A1b and A2b form a stack tunnel T1 with a profile tapered from bottom to top. That is, the inlet E1a is larger than the outlet E2a. In other words, in this embodiment, the stack tunnel T1 is designed as a constricted design along the opposite direction of the gravitational field. The constricted design may have an angle of inclination within the range of 90 degrees to improve the stack effect.

It should be noted that the sidewalls A1a, A2a, A1b and A2b shown in FIG. 5B and FIG. 5C may be regarded as the sidewalls 112 and 114 shown in FIG. 2, and, of course, may also be regarded as the sidewalls 116 and 118 shown in FIG. 1. In other words, the invention converts the one-dimensional heat source into the two-dimensional heat source by the heat dissipation module 130 so as to expand the contact area with the air in the stack tunnel. Therefore, more air inlets may be disposed to increase the air flow of the stack effect.

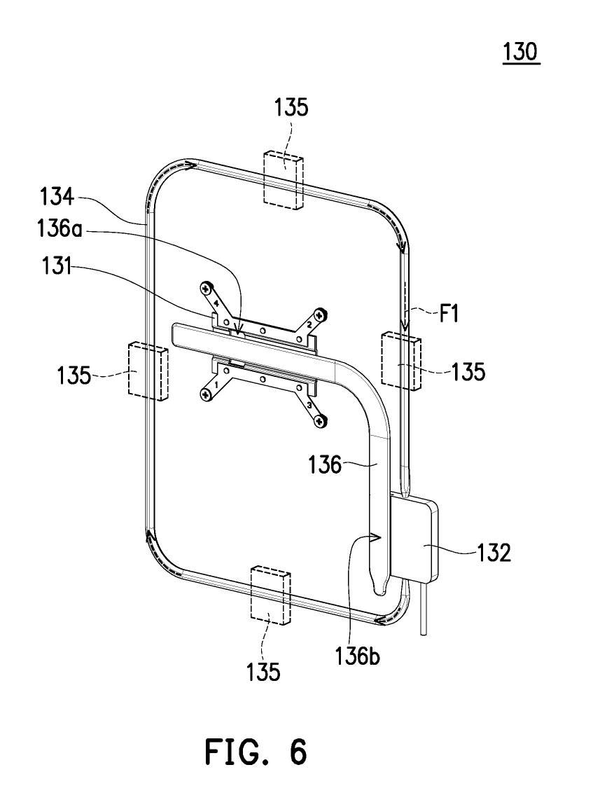

Referring to FIG. 3 and FIG. 4 again, in the embodiment shown in FIG. 3 and FIG. 4, the evaporator 132 and the pipe 134 are disposed on the plate 138 which is thermal conductive, so the heat may be further extended to the plate 138, such that the loop formed by the evaporator 132 and the pipe 134 and the plate 138 are regarded as the surface heat source under the two-dimensional manner. However, this embodiment is not limited thereto. FIG. 6 is a schematic view of a heat dissipation module according to another embodiment of the invention. Different from the foregoing embodiments, the heat dissipation module of this embodiment includes an evaporator 132, a pipe 134, a working fluid F1, a heat pipe 136, and assembling elements 131 and 135, wherein the features and relationships of the evaporator 132, the pipe 134, the working fluid F1, the heat pipe 136 and the assembling element 131 are as described in the foregoing embodiments, and the difference is in that the pipe 134 is fixed onto the motherboard 122 by the assembling element 135. That is to say, in this embodiment, the loop formed by connecting the evaporator 132 and the pipe 134 is used to heat the air in the stack tunnel T1. Therefore, the loop becomes a linear heat source to heat the air in the stack tunnel T1, and the effect of expanding the heat source area can also be achieved.

Referring to FIG. 1 and FIG. 2 again, in this embodiment, the electronic device 100 further includes a thermal conductive pad 140 which abuts between the plate 138 and the sidewall 114. In this way, the heat in the plate 138 may also be transferred to the sidewall 114, so the sidewall 114 may also be regarded as a heat source which provides heating effect to the stack tunnel T1. Thereby, the heat transfer efficiency between the heat dissipation module 130 and the air in the stack tunnel T1 increases, and the heat dissipation effect thereof also increases.

In summary, in the foregoing embodiments of the invention, the heat dissipation system of the electronic device provides a heat transfer to the air in the stack tunnel in the two-dimensional manner by forming the stack tunnel in the body, increasing the heat capacity of the heat source via the heat dissipation module, and expanding the contact with the air in the stack tunnel at the same time. Therefore, the electronic device can utilize the stack effect to achieve the heat dissipation effect, and at the same time, the structural restriction of the channel inlet resulted from the stack effect due to the position of the original heat source can be released.

Furthermore, the heat dissipation module is configured to dispose the evaporator and the pipe on the plate, so the heat can be uniformly transferred to the plate. The loop formed by the evaporator and the pipe and the plate thereby form a two-dimensional surface heat source in the stack tunnel, and the heat distribution on the surface heat source is uniform with a smaller temperature gradient so that the surface heat source may further uniformly heat the air in the stack channel. Compared with the prior art in which the heat source directly contacts the air in the stack tunnel, the embodiment of the invention can effectively increase the heat capacity and the contact area with air by the two-dimensional heating manner provided by the heat dissipation module to solve the problem of non-uniform and unstable heating of the air in the stack tunnel originally caused by only point heat sources.

Although the disclosure has been described with reference to the above embodiments, it will be apparent to one of ordinary skill in the art that modifications to the described embodiments may be made without departing from the spirit of the invention. Accordingly, the scope of the invention will be defined by the attached claims and not by the above detailed descriptions.

What is claimed is:

1. A heat dissipation system of an electronic device for dissipating heat from at least one heat source of the electronic device, the heat dissipation system of the electronic device comprising:
a body having a stack tunnel, wherein the at least one heat source is disposed in the body; and
a heat dissipation module comprising an evaporator and a pipe connecting to the evaporator, wherein the evaporator and the pipe form a loop, and a working fluid is filled in the loop, the evaporator is in thermal contact with the heat source to absorb heat, and the heat generated from the heat source is transferred to the loop through phase transition of the working fluid, and the loop heats the air in the stack tunnel in a two-dimensional manner.

2. The heat dissipation system of the electronic device as recited in claim 1, wherein the electronic device is an All-in-One PC (AIO PC) device.

3. The heat dissipation system of the electronic device as recited in claim 1, wherein the heat dissipation module is a two-phase flow heat dissipation module.

4. The heat dissipation system of the electronic device as recited in claim 1, wherein the heat dissipation module further comprises a plate which is thermally conductive, and the evaporator and the pipe are disposed on the plate.

5. The heat dissipation system of the electronic device as recited in claim 4, further comprising a thermal conductive pad abutting between the plate and a sidewall of the body to make the plate and the sidewall opposite to each other.

6. The heat dissipation system of the electronic device as recited in claim 4, wherein the plate and the loop form a surface heat source to heat the air in the stack tunnel.

7. The heat dissipation system of the electronic device as recited in claim 1, wherein the stack tunnel has a profile tapered from bottom to top.

8. The heat dissipation system of the electronic device as recited in claim 1, wherein the body further has a plurality of openings adjacent to and in communication with an inlet of the stack tunnel.

9. The heat dissipation system of the electronic device as recited in claim 1, wherein the loop forms a linear heat source to heat the air in the stack tunnel.
